(19) United States
(12) Patent Application Publication
(10) Pub. No.: US 2016/0050752 A1
(43) Pub. Date: Feb. 18, 2016

(54) PRINTED CIRCUIT BOARD AND METHOD OF MANUFACTURING THE SAME

(71) Applicant: SAMSUNG ELECTRO-MECHANICS CO., LTD, Suwon-Si (KR)

(72) Inventors: Myung Sam KANG, Suwon-Si (KR); Seung Eun LEE, Suwon-Si (KR); Young Kwan LEE, Suwon-Si (KR); Seung Yeop KOOK, Suwon-Si (KR); Ki Jung SUNG, Suwon-Si (KR)

(21) Appl. No.: 14/691,115

(22) Filed: Apr. 20, 2015

(30) Foreign Application Priority Data
Aug. 14, 2014 (KR) 10-2014-0105904

(51) Int. Cl. H05K 1/11; H05K 3/30; H05K 1/09

(52) U.S. Cl. CPC H05K 1/111; H05K 1/092; H05K 3/30

(57) ABSTRACT

There are provided a printed circuit board including: an insulation layer; circuit patterns buried in the insulation layer; and a bump pad having a lower part buried in the insulation layer and an upper part protruding upwardly from the insulation layer, and a method of manufacturing the printed circuit board.

### CROSS-REFERENCE TO RELATED APPLICATION

This application claims the benefit of Korean Patent Application No. 10-2014-0105904, filed on Aug. 14, 2014, entitled “Printed Circuit Board and Method of Manufacturing The Same” which is hereby incorporated by reference in its entirety into this application.

### BACKGROUND

The present disclosure relates to a printed circuit board and a method of manufacturing the same.

An external apparatus such as a semiconductor chip, or the like, may be mounted on a printed circuit board. In order to mount the external apparatus on the printed circuit board as described above, a bump pad for mounting the external apparatus and a solder resist for exposing an upper part of the bump pad may be formed on the outermost layer of the printed circuit board. The exposed bump pad and the external apparatus are electrically connected to each other.

### RELATED ART DOCUMENT

### Patent Document

(Patent Document 1) U.S. Pat. No. 8,039,761

### SUMMARY

An aspect of the present disclosure may provide a printed circuit board capable of preventing short-circuit between a bump pad and circuit patterns, and a method of manufacturing the same.

According to an aspect of the present disclosure, a printed circuit board may include: an insulation layer; circuit patterns buried in the insulation layer; and a bump pad having a lower part buried in the insulation layer and an upper part protruding upwardly from the insulation layer.

The protective layer may be made of a photosensitive insulation material.

The bump pad may include a metal layer and a barrier layer formed on a side surface of the metal layer.

The barrier layer may be made of a material different from that of the metal layer.

According to another aspect of the present disclosure, a method of manufacturing a printed circuit board may include: forming a groove curved inwardly on an upper surface of a carrier substrate; forming a barrier layer on an upper part of the carrier substrate and on an inner wall of the groove; forming a metal layer formed on the groove and the upper part of the carrier substrate so as to protrude upwardly from the carrier substrate; forming an insulation layer on the upper part of the carrier substrate; removing the carrier substrate; and forming a bump pad and circuit patterns by removing a portion of the barrier layer exposed to the outside.

The forming of the groove in the carrier substrate may include: forming a protective layer in which an opening part is patterned on the upper part of the carrier substrate so as to expose a region in which the groove is to be formed; and etching the region exposed by the opening part of the protective layer.

The protective layer may be made of a photosensitive insulation material.

The barrier layer may be made of a material different from that of a first metal layer.

The barrier layer may be made of a material different from that of the carrier substrate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified diagram illustrating a printed circuit board according to an exemplary embodiment of the present disclosure; and

FIGS. 2 through 16 are exemplified diagrams illustrating a method of manufacturing a printed circuit board according to exemplary embodiments of the present disclosure.

### DESCRIPTION OF EMBODIMENTS

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

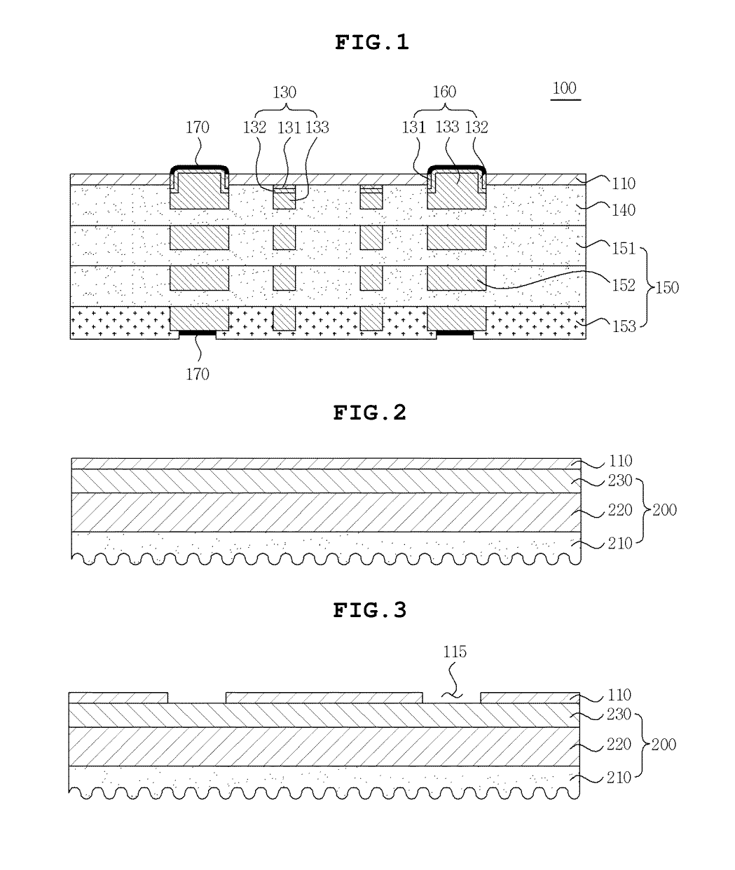

FIG. 1 is an exemplified diagram illustrating a printed circuit board according to an exemplary embodiment of the present disclosure.

Referring to FIG. 1, a printed circuit board 100 includes an insulation layer 140, a protective layer 110, a bump pad 160, circuit patterns 130, and a build up layer 150.

According to the exemplary embodiment of the present disclosure, the insulation layer 140 is made of a complex polymer resin generally used as an interlayer insulation material. For example, the insulation layer 140 is made of a prepreg, an Ajinomoto build up film (ABF), or an epoxy-based resin such as FR-4, bismaleimide triazine (BT), or the like.

According to the exemplary embodiment of the present disclosure, the protective layer 110 is formed on the insulation layer 140. According to the exemplary embodiment of the present disclosure, the protective layer 110 is made of a photosensitive insulation material.

According to the exemplary embodiment of the present disclosure, the bump pad 160 has a lower part which is buried in the insulation layer 140 and the protective layer 110. In addition, the bump pad 160 has an upper part protruding from the insulation layer 140 and the protective layer 110 to the outside.

According to the exemplary embodiment of the present disclosure, the bump pad 160 includes a barrier layer 131, a first metal layer 132, and a second metal layer 133. According to the exemplary embodiment of the present disclosure, the barrier layer 131 is formed on side surface of the second metal layer 133. In addition, the barrier layer 131 is formed in the protective layer 110 to contact the protective layer 110.

According to the exemplary embodiment of the present disclosure, the barrier layer 131, the first metal layer 132, and the second metal layer 133 are made of a conductive metal used in a circuit board field. In addition, the barrier layer 131 is made of a material different from that of the first metal layer 132. According to the exemplary embodiment of the present disclosure, the barrier layer 131 is made of a conductive metal having chemical resistance to an etching solution of the first metal layer 132. For example, when the first metal layer 132 is made of copper, the barrier layer 131 is made of nickel or titanium.

In addition, according to the exemplary embodiment of the present disclosure, the second metal layer 133 is made of the same material as the first metal layer 132. For example, the second metal layer 133 is made of copper. However, the second metal layer 133 is not necessarily made of the same material as the first metal layer 132.

According to the exemplary embodiment of the present disclosure, the circuit patterns 130 are buried in the insulation layer 140. In addition, an upper surface of the circuit patterns 130 is covered by the protective layer 110 to be protected from the outside.

According to the exemplary embodiment of the present disclosure, the circuit patterns 130 include a barrier layer 131, a first metal layer 132, and a second metal layer 133.

According to the exemplary embodiment of the present disclosure, the printed circuit board 100 has a structure in which the circuit patterns 130 are covered with the protective layer 110, and the bump pad 160 only protrudes to the outside. Therefore, it is possible to prevent contact between surrounding circuits (circuit patterns) and an adhesive which is pushed out by a pressure when the bump pad 160 is adhered to an external component (not shown). Here, for example, the adhesive may be a solder. That is, a short-circuit of the bump pad 160 and the surrounding circuit patterns 130 due to the solder pushed out when the printed circuit board 100 is adhered to the external component (not shown) may be prevented.

According to the exemplary embodiment of the present disclosure, the build up layer 150 is formed on a lower part of the insulation layer 140.

According to the exemplary embodiment of the present disclosure, the build up layer 150 includes a build up insulation layer 151, a build up circuit layer 152, and a solder resist layer 153.

According to the exemplary embodiment of the present disclosure, the build up insulation layer 151 is made of a complex polymer resin generally used as an interlayer insulation layer. For example, the build up insulation layer 151 is made of a prepreg, an Ajinomoto build up film (ABF), or an epoxy-based resin such as FR-4, bismaleimide triazine (BT), or the like.

According to the exemplary embodiment of the present disclosure, the build up circuit layer 152 is formed in an inner part and a lower part of the build up insulation layer 151. According to the exemplary embodiment of the present disclosure, the build up circuit layer 152 is made of a conductive metal used in the circuit board field.

According to the exemplary embodiment of the present disclosure, the solder resist layer 153 is formed in the lower part of the build up insulation layer 151 to surround the build up circuit layer 152. In addition, the solder resist layer 153 is patterned so that a portion of the build up circuit layer 152 electrically connected to the external component is exposed to the outside. According to the exemplary embodiment of the present disclosure, the solder resist layer 153 is made of a heat resistant covering material.

In the exemplary embodiment of the present disclosure, the build up layer 150 includes the build up insulation layer 151 in two layers, the build up circuit layer 152 in three layers, and the solder resist layer 153; however, the build up layer 150 is not limited thereto in view of a structure. That is, in the build up layer 150, the number of build up insulation layers 151, the number of build up circuit layers 152, and the number of solder resist layers 153 may be changed, and the build up insulation layer 151, the build up circuit layer 152, and the solder resist layer 153 may be omitted.

According to the exemplary embodiment of the present disclosure, a surface treatment layer 170 is formed on a surface of the bump pad 160 and a surface of the build up circuit layer 152 exposed to the outside. According to the exemplary embodiment of the present disclosure, the surface treatment layer 170 is formed to prevent an oxidation film from being formed on the surface of the bump pad 160 and the build up circuit layer 152. For example, the surface treatment layer 170 is formed by plating nickel, tin, gold, palladium, or the like. In addition, the surface treatment layer 170 is formed by coating an organic solderability preservative (OSP). The surface treatment layer 170 may be formed by surface treatment methods known in the circuit board field. The surface treatment layer 170 may be omitted according to selection of a person skilled in the art.

In addition, although not shown in FIG. 1, the build up layer 150 may have vias (not shown) electrically connecting the build up circuit layers 152 formed on different layers to each other.

FIGS. 2 through 16 are exemplified diagrams illustrating a method of manufacturing a printed circuit board according to exemplary embodiments of the present disclosure.

The method of manufacturing the printed circuit board 100 of FIG. 1 is shown in FIGS. 2 through 16. Here, for convenience of explanation, the printed circuit board 100 having upper and lower parts reversed on the basis of the printed circuit board 100 of FIG. 1 is shown in FIGS. 2 through 14.

Referring to FIG. 2, the protective layer 110 is formed on the carrier substrate 200.

According to the exemplary embodiment of the present disclosure, the carrier substrate 200 includes a carrier core 210, a first carrier metal layer 220, and a second carrier metal layer 230.

The carrier core 210 according to the exemplary embodiment of the present disclosure is made of a resin insulation material. For example, the carrier core 210 may be made of a thermosetting resin such as an epoxy resin or a thermoplastic resin such as polyimide. Otherwise, the carrier core 210 may be made of prepreg impregnated with a reinforcing agent such as glass fiber or inorganic filler in the thermosetting resin or the thermoplastic resin.

The first carrier metal layer 220 according to the exemplary embodiment of the present disclosure is formed on one surface of the carrier core 210. Although a structure in which the first carrier metal layer 220 is formed on one surface of the carrier core 210 is shown in the exemplary embodiment of the present disclosure, the carrier substrate 200 is not limited to this structure. That is, the first carrier metal layers 220 may be formed on both surfaces of the carrier core 210.

The second carrier metal layer 230 according to the exemplary embodiment of the present disclosure is formed on one surface of the first carrier metal layer 220.

According to the exemplary embodiment of the present disclosure, it is shown that the first carrier metal layer 220 is thicker than the second carrier metal layer 230. However, the carrier substrate 200 is not necessarily limited thereto in view of a structure. In the exemplary embodiment of the present disclosure, the second carrier metal layer 230 has a thickness larger than a depth of a groove (not shown) to be formed.

According to the exemplary embodiment of the present disclosure, the first carrier metal layer 220 and the second carrier metal layer 230 are made of a conductive metal. For example, the first carrier metal layer 220 and the second carrier metal layer 230 are made of copper.

On an upper part of the carrier substrate 200 formed as described above, the protective layer 110 is formed. In the exemplary embodiment of the present disclosure, it is shown that the protective layer 110 is formed on one surface of the carrier substrate 200. However, if the carrier substrate 200, that is, all of the first carrier metal layer 220 and the second carrier metal layer 230 are formed on both surfaces of the carrier core 210, it is also possible to form the protective layer 110 on both surfaces of the carrier substrate 200.

According to the exemplary embodiment of the present disclosure, the protective layer 110 is made of a photosensitive insulation material used in the circuit board field.

Referring to FIG. 3, the protective layer 110 is patterned.

According to the exemplary embodiment of the present disclosure, an opening part 115 is formed by performing an exposure process and a development process on the protective layer 110. According to the exemplary embodiment of the present disclosure, the opening part 115 is to be formed so that a region in which the groove (not shown) is formed later is exposed to the outside.

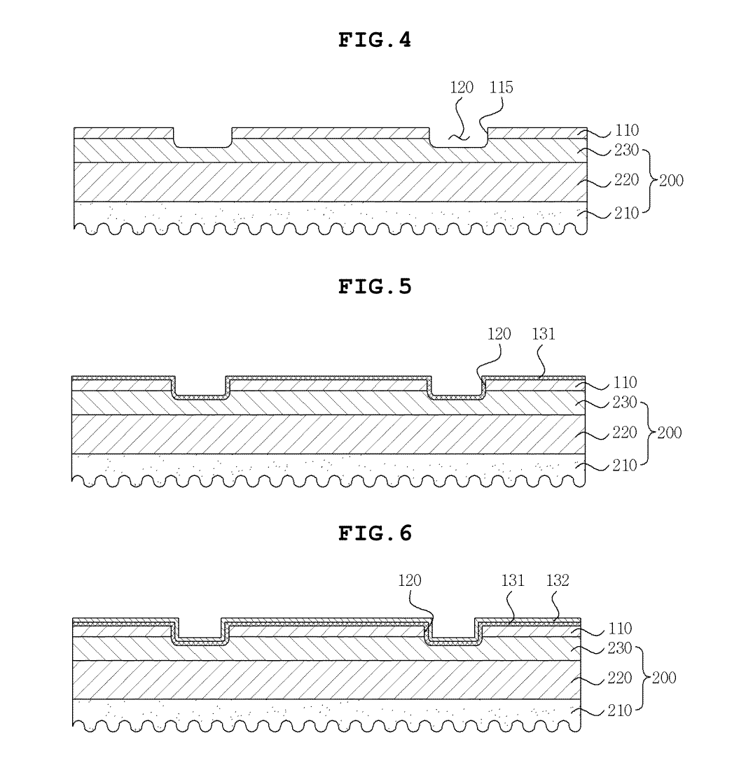

Referring to FIG. 4, the groove 120 is formed.

According to the exemplary embodiment of the present disclosure, an etching process is performed on the second carrier metal layer 230 exposed by the opening part 115 of the protective layer 110 to thereby form the groove 120. According to the exemplary embodiment of the present disclosure, the groove 120 has a depth as a thickness at which the bump pad (not shown) to be formed protrudes.

According to the exemplary embodiment of the present disclosure, the groove 120 may be formed by using an etching solution or laser drill.

Referring to FIG. 5, the barrier layer 131 is formed.

According to the exemplary embodiment of the present disclosure, the barrier layer 131 is formed on a surface of the protective layer 110 and an inner wall of the groove 120. According to the exemplary embodiment of the present disclosure, the barrier layer 131 is formed by an electroless plating method. For example, the barrier layer 131 is formed by physical vapor deposition (PVD). However, a method of forming the barrier layer 131 is not limited thereto, and the barrier layer 131 may be formed by any electroless plating method.

According to the exemplary embodiment of the present disclosure, the barrier layer 131 is made of a conductive metal. Here, the barrier layer 131 is made of a material different from that of the second carrier metal layer 230. That is, the barrier layer 131 is made of a conductive metal which does not react with the etching solution reacting with the second carrier metal layer 230. For example, when the second carrier metal layer 230 is made of copper, the barrier layer 131 is made of nickel or titanium having chemical resistance to a copper etching solution.

According to the exemplary embodiment of the present disclosure, when the second carrier metal layer 230 is removed later by the barrier layer 131 made of the above-described materials, the bump pad (not shown) and the circuit patterns (not shown) are protected from the etching solution.

Referring to FIG. 6, the first metal layer 132 is formed.

According to the exemplary embodiment of the present disclosure, the first metal layer 132 is formed on an upper part of the barrier layer 131. According to the exemplary embodiment of the present disclosure, the first metal layer 132 is formed by an electroless plating method. For example, the first metal layer 132 is formed by physical vapor deposition (PVD). However, a method of forming the first metal layer 132 is not limited thereto, and the first metal layer 132 may be formed by any electroless plating method.

According to the exemplary embodiment of the present disclosure, the first metal layer 132 is made of a conductive metal. Here, the first metal layer 132 is made of a material different from that of the barrier layer 131. That is, the first metal layer 132 is made of a conductive metal which does not react with the etching solution reacting with the barrier layer 131. Therefore, when the barrier layer 131 is removed later, it is possible to prevent etching of the first metal layer 132 by the etching solution to be used. For example, the first metal layer 132 is made of copper.

According to the exemplary embodiment of the present disclosure, the forming of the first metal layer 132 may be omitted according to selection of a person skilled in the art.

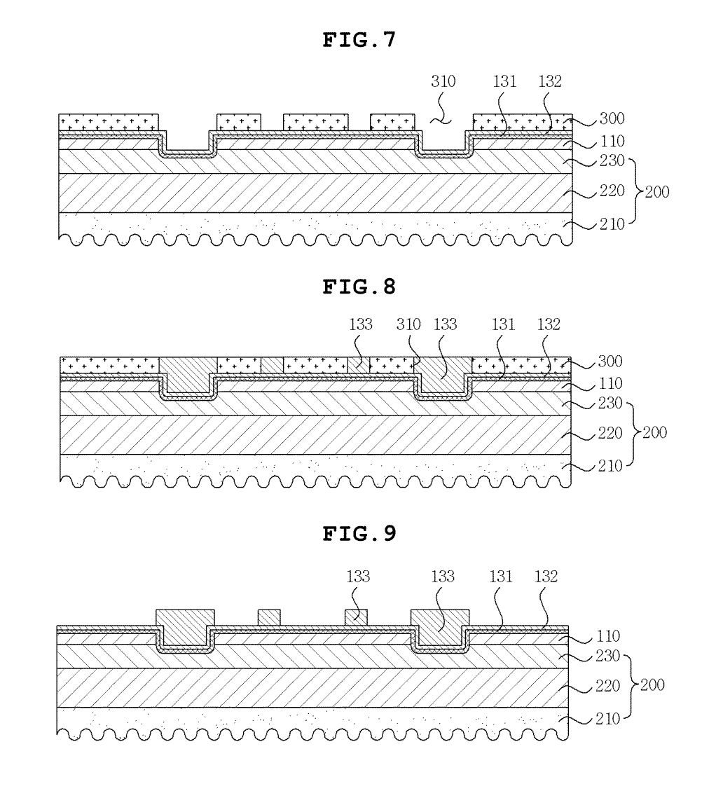

Referring to FIG. 7, a plating resist 300 is formed.

According to the exemplary embodiment of the present disclosure, the plating resist 300 is formed on an upper part of the first metal layer 132. In addition, the plating resist 300 includes a plating opening part 310. Here, the plating opening part 310 is formed so as to expose a region in which the bump pad (not shown) and the circuit patterns (not shown) are formed. Therefore, the plating opening part 310 is positioned on an upper part of the groove 120 formed in the second carrier metal layer 230.

Referring to FIG. 8, a plating process is performed.

According to the exemplary embodiment of the present disclosure, the second metal layer 133 is formed in the plating opening part 310 by an electroplating method. According to the exemplary embodiment of the present disclosure, the second metal layer 133 is made of a conductive metal used in the circuit board field. For example, the second metal layer 133 is made of copper.

Referring to FIG. 9, the plaiting resist (300 in FIG. 8) is removed.

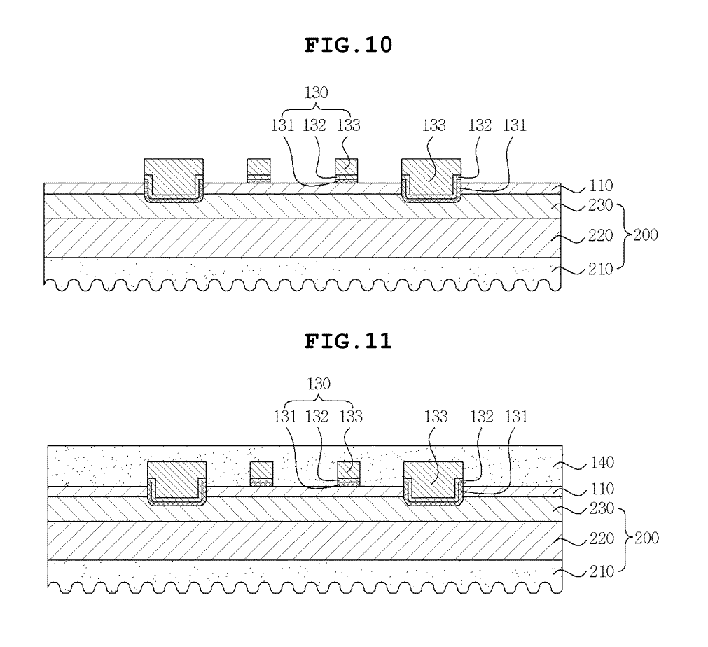

Referring to FIG. 10, the barrier layer 131 and the first metal layer 132 exposed to the outside are removed.

According to the exemplary embodiment of the present disclosure, a portion of the first metal layer 132 is exposed to the outside while removing the plating resist (300 in FIG. 8). First, the first metal layer 132 exposed to the outside is removed.

In addition, when the first metal layer 132 is removed, a portion of the barrier layer 131 is exposed to the outside. Therefore, after the first metal layer 132 is removed, the barrier layer 131 exposed to the outside is also removed. As described above, when the barrier layer 131 and the first metal layer 132 exposed to the outside are removed, the circuit patterns 130 are formed. According to the exemplary embodiment of the present disclosure, the circuit patterns 130 include a barrier layer 131, a first metal layer 132, and a second metal layer 133. Here, one surface of the barrier layer 131 included in the circuit patterns 130 contacts the protective layer 110.

Referring to FIG. 11, the insulation layer 140 is formed.

According to the exemplary embodiment of the present disclosure, the insulation layer 140 is formed in an upper part of the second carrier metal layer 230. The insulation layer 140 formed as described above is formed so as to bury the second metal layer 133.

According to the exemplary embodiment of the present disclosure, the insulation layer 140 may be formed in the upper part of the second carrier metal layer 230, as a film form, by stacking and pressurizing methods. Otherwise, the insulation layer 140 may be formed in the upper part of the second carrier metal layer 230 by applying a material in a liquid phase for forming the insulation layer.

According to the exemplary embodiment of the present disclosure, the insulation layer 140 is made of a complex polymer resin generally used as an interlayer insulation material. For example, the insulation layer 140 is made of a prepreg, an Ajinomoto build up film (ABF), an epoxy-based resin such as FR-4, bismaleimide triazine (BT), or the like.

According to the exemplary embodiment of the present disclosure, the circuit patterns 130 are buried in the insulation layer 140.

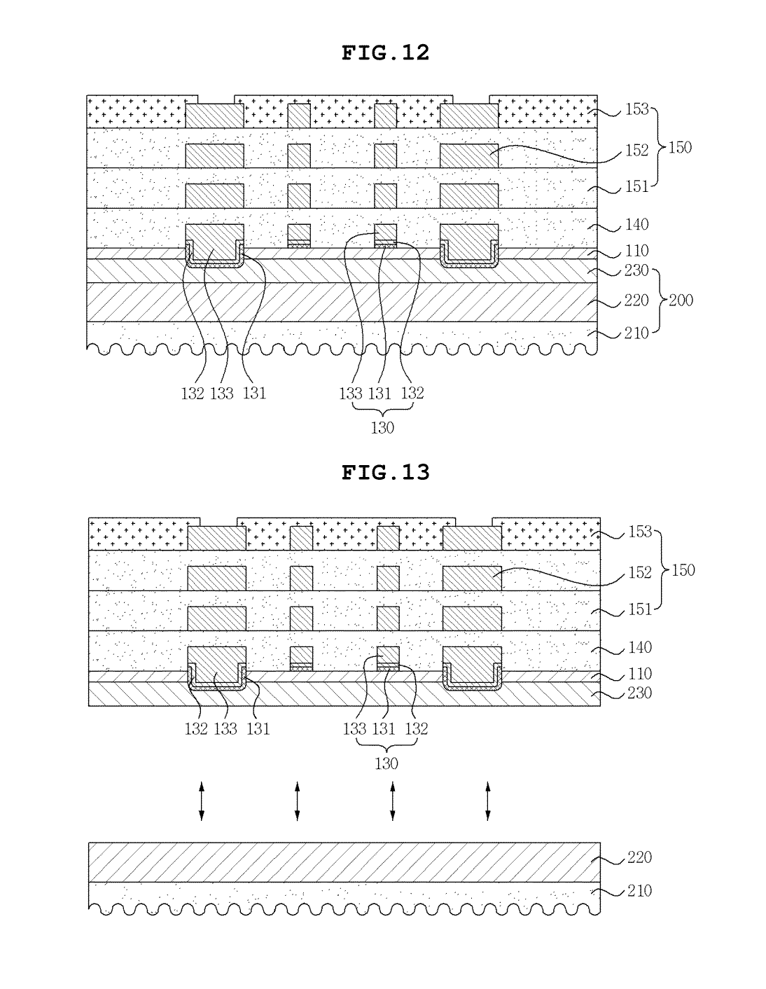

Referring to FIG. 12, the build up layer 150 is formed.

According to the exemplary embodiment of the present disclosure, the build up layer 150 is formed on an upper part of the insulation layer 140.

According to the exemplary embodiment of the present disclosure, the build up layer 150 includes the build up insulation layer 151, the build up circuit layer 152, and the solder resist layer 153.

According to the exemplary embodiment of the present disclosure, the build up insulation layer 151 is made of a complex polymer resin generally used as an interlayer insulation material. For example, the build up insulation layer 151 is made of a prepreg, an Ajinomoto build up film (ABF), an epoxy-based resin such as FR-4, bismaleimide triazine (BT), or the like.

According to the exemplary embodiment of the present disclosure, the build up circuit layer 152 is formed in an inner part and an upper part of the build up insulation layer 151. According to the exemplary embodiment of the present disclosure, the build up circuit layer 152 is made of a conductive metal used in the circuit board field.

According to the exemplary embodiment of the present disclosure, the solder resist layer 153 is formed in the upper part of the build up insulation layer 151 to surround the build up circuit layer 152. In addition, the solder resist layer 153 is patterned so that a portion of the build up circuit layer 152 electrically connected to the external component is exposed to the outside. According to the exemplary embodiment of the present disclosure, the solder resist layer 153 is made of a heat resistant covering material.

According to the exemplary embodiment of the present disclosure, the build up layer 150 is formed by a method of forming the insulation layer, the circuit layer, and the solder resist which are known in the circuit board field.

In addition, although not shown in FIG. 12, the build up layer 150 may have vias (not shown) electrically connecting the build up circuit layers 152 to each other, wherein the build up circuit layers are formed on different layers.

Referring to FIG. 13, the first carrier metal layer 220 is separated from the second carrier metal layer 230.

Referring to FIG. 14, the second carrier metal layer 230 in FIG. 14 is removed.

According to the exemplary embodiment of the present disclosure, the second carrier metal layer 230 in FIG. 14 is removed by the etching solution.

In the exemplary embodiment of the present disclosure, the barrier layer 131 is made of a material having chemical resistance to an etching solution of the second carrier metal layer 230 in FIG. 14. Therefore, when the second carrier metal layer 230 in FIG. 14 is removed, the barrier layer 131 is not removed, and the first metal layer 132 and the second metal layer 133 are protected from the etching solution to be used.

Although it is not shown in FIG. 14, a separate protective layer is formed even on an upper part of the build up circuit layer 152 exposed to the outside by the solder resist layer 153 to protect the build up circuit layer 152 from the etching solution.

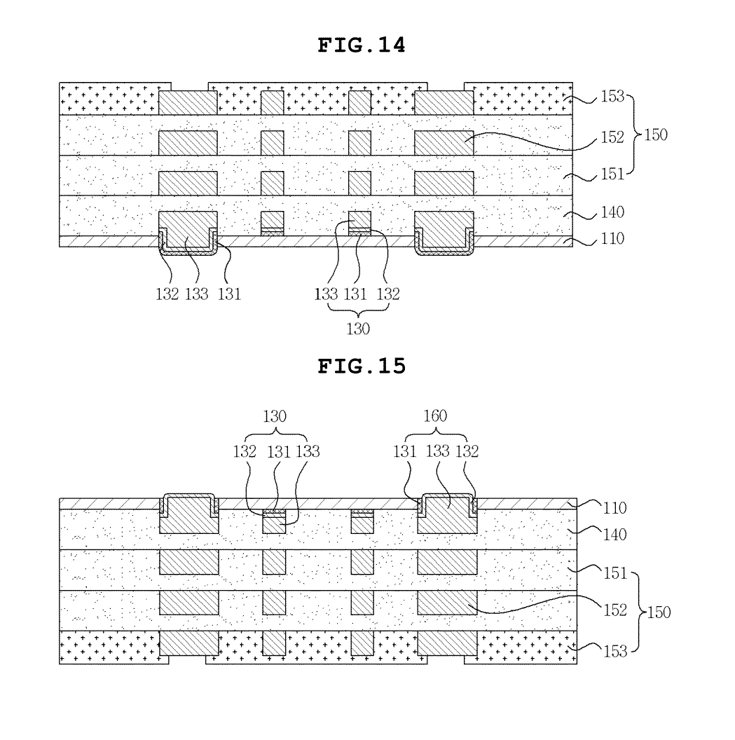

Referring to FIG. 15, the barrier layer 131 exposed to the outside is removed.

According to the exemplary embodiment of the present disclosure, the first carrier metal layer 220 in FIG. 14 is removed, such that a portion of the barrier layer 131 is exposed to the outside. The barrier layer 131 exposed to the outside as described above is removed by the etching solution.

In the exemplary embodiment of the present disclosure, the first metal layer 132 is made of a metal having chemical resistance to the etching solution of the barrier layer 131. Therefore, when the barrier layer 131 is removed, the first metal layer 132 is not removed, and the second metal layer 133 is protected from the etching solution to be used.

According to the exemplary embodiment of the present disclosure, the barrier layer 131 is not completely removed. A portion of the barrier layer 131 formed in the protective layer 110 is protected from the etching solution and is maintained.

According to the exemplary embodiment of the present disclosure, the bump pad 160 is formed by removing the barrier layer 131 exposed to the outside. According to the exemplary embodiment of the present disclosure, the bump pad 160 includes a first metal layer 132, a second metal layer 133, and a barrier layer 131. According to the exemplary embodiment of the present disclosure, the barrier layer 131 is formed on the side surface of the bump pad 160 and the barrier layer 131 contacts the protective layer 110. In addition, one portion of the bump pad 160 is buried in the protective layer 110 and the insulation layer 140, and other portion thereof protrudes from the protective layer 110 and the insulation layer 140.

In addition, according to the exemplary embodiment of the present disclosure, one surface of the circuit patterns 130 buried in the insulation layer 140 is covered with the protective layer 110 to be protected from the outside.

Through the above-described processes, the printed circuit board 100 of FIG. 1 is formed. The printed circuit board 100 having upper and lower parts reversed on the basis of the printed circuit board 100 of FIG. 1 is shown in FIG. 15.

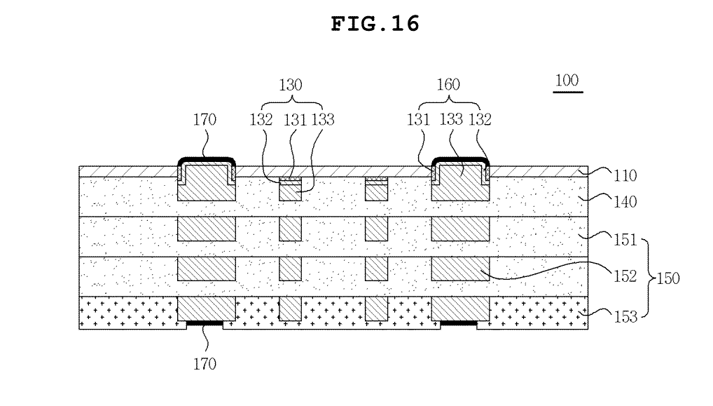

Referring to FIG. 16, the surface treatment layer 170 is formed.

According to the exemplary embodiment of the present disclosure, the surface treatment layer 170 may be further formed on the surface of the bump pad 160 and the surface of the build up circuit layer 152 exposed to the outside.

According to the exemplary embodiment of the present disclosure, the surface treatment layer 170 is formed so as to prevent an oxidation film from being formed on the surfaces of the bump pad 160 and the build up circuit layer 152. For example, the surface treatment layer 170 is formed by plating nickel, tin, gold, palladium, or the like. In addition, the surface treatment layer 170 is formed by coating an organic solderability preservative (OSP). As described above, the surface treatment layer 170 may be formed by surface treatment methods known in the circuit board field.

Although the printed circuit board 100 formed on one surface of the carrier substrate 200 is illustrated in the exemplary embodiments of the present disclosure, the present disclosure is not limited thereto. For example, the printed circuit boards 100 may be formed on both surfaces of the carrier substrate 200. In this case, two printed circuit boards 100 may be formed at the same time.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
an insulation layer;
circuit patterns buried in the insulation layer; and
a bump pad having a lower part buried in the insulation layer and an upper part protruding upwardly from the insulation layer.

2. The printed circuit board of claim 1, further comprising:
a protective layer formed on the insulation layer to cover the insulation layer and the circuit patterns.

3. The printed circuit board of claim 2, wherein the protective layer is made of a photosensitive insulation material.

4. The printed circuit board of claim 2, wherein the bump pad includes a metal layer and a barrier layer formed on a side surface of the metal layer.

5. The printed circuit board of claim 4, wherein the barrier layer contacts the protective layer.

6. The printed circuit board of claim 4, wherein the barrier layer is made of a material different from that of the metal layer.

7. A method of manufacturing a printed circuit board, comprising:
forming a groove curved inwardly on an upper surface of a carrier substrate;
forming a barrier layer on an upper part of the carrier substrate and on an inner wall of the groove;
forming a metal layer formed in the groove and the upper part of the carrier substrate so as to protrude upwardly from the carrier substrate;
forming an insulation layer on the upper part of the carrier substrate;
removing the carrier substrate; and
forming a bump pad and circuit patterns by removing a portion of the barrier layer exposed to the outside.

8. The method of claim 7, wherein the forming of the groove in the carrier substrate includes:
forming a protective layer in which an opening part is patterned on the upper part of the carrier substrate so as to expose a region in which the groove is to be formed; and
etching the region exposed by the opening part of the protective layer.

9. The method of claim 8, wherein in the forming of the barrier layer, the barrier layer is formed on an upper surface and side surfaces of the protective layer, and the inner wall of the groove.

10. The method of claim 8, wherein the protective layer is made of a photosensitive insulation material.

11. The method of claim 7, wherein the barrier layer is made of a material different from that of a first metal layer.

12. The method of claim 7, wherein the barrier layer is made of a material different from that of the carrier substrate.

13. The method of claim 7, wherein in the forming of the groove in the carrier substrate, the carrier substrate includes a first carrier metal layer and a second carrier metal layer formed on an upper part of first carrier metal layer.

14. The method of claim 13, wherein in the forming of the groove in the carrier substrate, the groove is formed in the first carrier metal layer.

15. The method of claim 14, wherein in the removing of the carrier substrate includes:
separating the first carrier metal layer from the second carrier metal layer; and
etching the first carrier metal layer with an etching solution.

16. The method of claim 15, wherein the etching solution reacts with the first carrier metal layer, but does not react with the barrier layer.
